(19) United States
(12) Patent Application Publication
(10) Pub. No.: US 2008/0179081 A1
(43) Pub. Date: Jul. 31, 2008

(54) Direct Applied Monolithic Printed Circuit Technology

(75) Inventor: Joseph P. Rao, Dublin, OH (US)

Correspondence Address: REINHART BOERNER VAN DEUREN P.C., 2215 PERRYGREEN WAY, ROCKFORD, IL, 61107, US

(73) Assignee: RANCO INCORPORATED OF DELAWARE, Wilmington, DE (US)

(21) Appl. No.: 11/626,940

(22) Filed: Jan. 25, 2007

(51) Int. Cl. H05K 1/03; H05K 3/00

(52) U.S. Cl. 174/255; 29/831

(57) ABSTRACT

An electronic circuit board is provided. The electronic circuit board includes a substrate and a conductive adhesive adhered to the substrate in a trace pattern. The conductive adhesive mechanically supports and electrically connects an electronic component.

### FIELD OF THE INVENTION

This invention relates generally to electronic circuits and, more particularly, to the layout and construction of printed electronic circuits.

### BACKGROUND OF THE INVENTION

In the electronics industry, printed circuit boards or PCB's are used to mechanically support and electrically connect electronic components. Such PCB's are mass produced using a variety of different techniques with the majority being formed from a cladding/etching process.

In the cladding/etching process, a conductive material (e.g., copper) is laminated or glued over a substrate of non-conductive or insulating material (e.g., woven fiberglass), a mask is placed over the conductive material, and any unwanted conductive material left exposed by the mask is chemically etched away. When the mask is removed, conductive pathways or traces of the conducting material remain. These traces provide locations for the electronic components to be attached using, for example, solder. As a result, the electronic components are adequately supported by, and electrically coupled through, the PCB.

Unfortunately, many of the prevalent cladding/etching processes are expensive, present potential environmental risks due to the hazardous materials involved, and result in a lengthy fabrication lead time. Even so, the cladding/etching processes are often used because they produce PCB's that permit electronic components to be quickly and easily electrically connected using tin/lead solder. However, recent compliance and regulatory issues with heavy metals have encouraged other soldering materials and other circuit board processes to be contemplated.

In addition to the above, PCB's produced using the standard cladding/etching processes have other significant drawbacks. For example, each of the PCB's requires at least one substrate layer to support the electronic components. The substrate layer takes up a significant amount of space within the housing of electronic device. These PCBs also typically require mechanical connectors to hold them in place within the housing, taking up additional room. As consumers and others demand smaller and smaller electronic devices, the use of any component that uses such a large portion of the area within the electronic device is undesirable.

Conventional PCB's also rely on a relatively costly metal conductive layer such as, for example, copper. As consumers and other demand less and less expensive electronic devices, the use of any component that adds to the overall unit cost of the electronic device is undesirable.

Therefore, an electric circuit that is mechanically supported and electrically connected without the use of a typical PCB would be desirable. The invention provides such an electronic circuit. These and other advantages of the invention, as well as additional inventive features, will be apparent from the description of the invention provided herein.

### BRIEF SUMMARY OF THE INVENTION

The invention provides an electronic circuit, and method of fabricating the same, that employs adjacent structure as a substrate for the circuit. As such, the electronic circuit is less costly to manufacture, takes up less space, and provides other advantages compared with the conventional PCB technology discussed above.

In one embodiment, an electronic circuit formed on a non-conductive substrate from a conductive adhesive adhered to the substrate in a trace pattern is provided. The conductive adhesive electrically connects the electronic components to form the electronic circuit.

In another embodiment, an electronic circuit for a consumer product formed on the housing of the consumer product from a conductive adhesive is provided. The housing of the consumer product includes an internal surface and the conductive adhesive is adhered to that internal surface. The electronic components of the electronic circuit are positioned and held by and electrically coupled via the conductive adhesive.

In yet another embodiment, a method of increasing useable space within a housing of a device is provided. The method includes the steps of adhering a conductive adhesive to the housing and electrically connecting electronic components with the conductive adhesive.

In another embodiment, a method of creating an electronic circuit on a non-conductive product is provided. The method includes the steps of adhering a conductive adhesive to the non-conductive product and electrically connecting electronic components using the conductive adhesive.

Other aspects, objectives and advantages of the invention will become more apparent from the following detailed description when taken in conjunction with the accompanying drawings.

### BRIEF DESCRIPTION OF THE DRAWINGS

The accompanying drawings incorporated in and forming a part of the specification illustrate several aspects of the present invention and, together with the description, serve to explain the principles of the invention. In the drawings:

FIG. 1 is a side elevation view of an exemplary embodiment of an electronic circuit constructed in accordance with the teachings of the present invention;

FIG. 2 is a top plan view of the electronic circuit of FIG. 1;

FIG. 3 is a perspective view of overlapping traces in one embodiment of the electronic circuit of FIG. 1, the electronic circuit having components thereon; and

FIG. 4 is a cross section view of layers of conductive adhesive stacked on a substrate and separated by an insulating layer in one embodiment of the electronic circuit of FIG. 1.

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

### DETAILED DESCRIPTION OF THE INVENTION

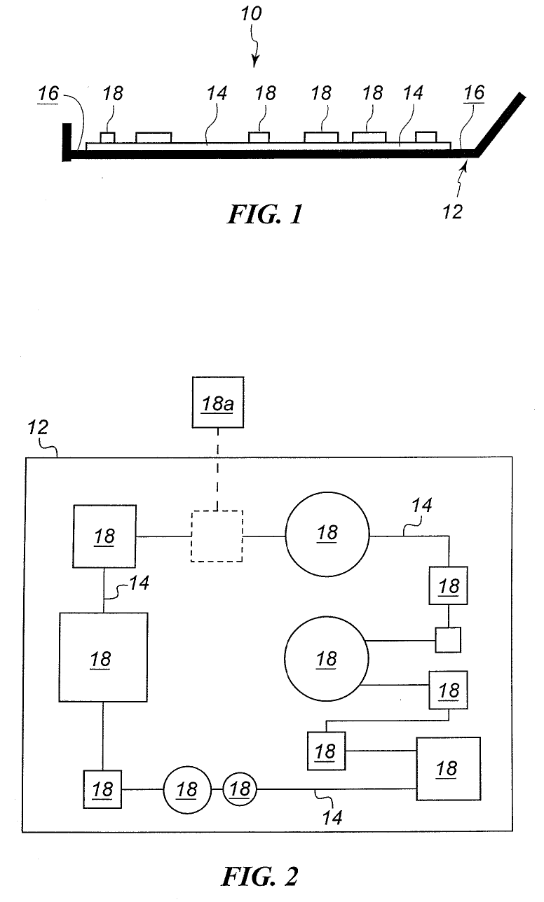

Referring to FIG. 1, an electronic circuit 10 or microelectronic assembly in accordance with the teachings of the present invention is illustrated. The electronic circuit 10 includes a substrate 12 and an electrically conductive adhesive 14 (ECA). In one embodiment, the substrate 12 is formed from a non-conductive material while, in another embodiment, the substrate 12 is made from a conductive or semi-conductive material and insulated by, for example, a conformal coating from the conductive adhesive 14.

In the illustrated embodiment as shown in FIG. 1, the substrate 12 is a portion of a housing from, for example, an electronic device (e.g., a cell phone, computer, radio, thermostat, etc.). Even so, in one embodiment the substrate 12 is a small area of paper from a greeting card, a promotional material, and the like. In yet another embodiment, the substrate 12 is a portion of glass or other type of insulating material from a retail product or a portion of a normal printed circuit board (PCB). As will be more fully explained below, the type and size of the substrate 12 is dependent upon the particular application or environment of the electronic circuit 10. The circuit does not require a separate PCB to mechanically support and electrically connect the components thereof. However, as will be discussed more fully below, the use of such PCBs is not precluded. Indeed, in applications that utilize separate or additional substrate structures to mechanically support the or additional circuits, certain advantages may be realized by using the printing of circuit traces using the conductive adhesive in accordance with the teachings of the present invention.

In one embodiment, the substrate 12 is generally formed from a material or materials not commonly found or expected in a standard or conventional printed circuit board (PCB). Such materials include, by way of example and not limitation, paper impregnated with phenolic resin, woven fiberglass mat impregnated with a flame resistant epoxy resin, plastics with low dielectric constant and dissipation factor, and the like specialty materials. Other materials commonly used to house consumer and commercial products may also form the substrate 12, provided that such materials are non-conductive or otherwise electrically insulated from the conductive adhesive 14 that forms the circuit traces of the present invention.

As shown, the substrate 12 defines a surface 16. In the illustrated embodiment, the surface 16 is an internal surface directed inwardly away from an external environment relative to the electronic device. In one embodiment, the surface 16 is on an external or interior portion of an electronic device, on a portion of a consumer or retail product, and the like. Although shown as a plane in FIG. 1, in one embodiment the surface 16 is contoured, uneven, or otherwise shaped. Indeed, through the present invention an electronic circuit may be formed on any housing, which removes the requirement that the housing be shaped to accommodate a conventional PCB.

Still referring to FIG. 1, the conductive adhesive 14 is generally placed upon and adhered to the surface 16 of the substrate 12. In one embodiment, the conductive adhesive 14 is a polymer binder infused with a conductive filler. In general, the polymer provides mechanical strength and the conductive filler (e.g., silver, nickel, gold, carbon, or some other metal or conductive material) provides the electrical conductivity. The conductive filler employed in the conductive adhesive 14 occupies a variety of different shapes (e.g., flakes, spheres, etc.) and is inserted in various concentration levels to achieve the desired conductivity.

Suitable conductive adhesives 14 for use in the electronic circuit 10 include, for example, conductive impregnated Epoxy, Cyanoacrylate, Polyurethane and Silicone adhesives. These conductive adhesives 14 can also be used as a base to support the appropriate substrate. In addition, the conductive adhesives 14 are able to adhere to paper, plastic, glass, and other surfaces. In one embodiment, the conductive adhesive 14 is used as a glue or laminate. The conductive adhesive 14 may be in the form of a tape, film, paste or other material. For example, the conductive adhesive 14 can be formed from a sticky-back tape. Also, both isotropically conductive adhesive (ICA) and anisotropically conductive adhesives (ACA) may be used for the conductive adhesive 14.

As shown in FIG. 2, the conductive adhesive 14 is employed (in the form of traces) to electrically connect and couple electronic components 18 to each other, to the substrate 12, and/or to further electronic circuits. In addition to providing electrical conductivity, the conductive adhesive 14 may be used to support the electronic components 18. As a result, all or substantially all of the electrical and mechanical connections formed in the electronic circuit 10 may be made using the conductive adhesive 14. Still referring to FIG. 2, one of the components, namely 18a, has lifted away from the substrate. The position that the removed component 18a would occupy on the circuit board is represented by dashed lines. Because the removed component 18a has been separated from the conductive adhesive 14, the circuit is broken at the location where the component 18a is missing.

In one embodiment, the conductive adhesive 14 remains flexible or semi-rigid after having been applied such that flexing, stretching, bending, or other movement of the substrate 12 is accommodated without damaging the electronic circuit 10. Because the conductive adhesive 14 has this feature, the electronic circuit 10 is useable in applications where a PCB with a stiff and inflexible substrate and/or brittle solder joints are not practicable or feasible.

The conductive adhesive 14 is applied to the surface 16 of the substrate 12 through a process of, for example, spraying, silk screening, X-Y plotting, printing, stenciling, or another suitable adhesive application or printing method. In one embodiment, the conductive adhesive 14 is situated on the surface 16 of the substrate 12 in a trace or circuit layout pattern similar to those formed during a conventional cladding/etching process. By applying the conductive adhesive 14 in such a pattern, the electronic components 18 are more easily and/or efficiently positioned on the electronic circuit 10.

In one embodiment, after the conductive adhesive 14 is applied to the surface 16 of the substrate 12, depending on the type of adhesive chosen the adhesive may be cured, baked, exposed to a solvent, exposed to an accelerant, or otherwise treated. For example, where a Cyanoacrylate adhesive is selected, either a chemical accelerant or Infrared (IR) radiation may be applied to control the cure rate of the application.

The electronic components 18 shown in FIG. 1 are, for example, discrete electronic components, integrated circuits in a variety of different packages, and the like. Preferably, the electronic components 18 utilize surface mount packaging. When an electronic component 18 having a “through hole” package is utilized, at least the leads of the electronic component are simply pressed into the conductive adhesive 14 to make the electrical connection and the electronic component is securely held in position. To provide additional support for such an electronic component, at least a portion of the component itself may also be held by the conductive adhesive.

As a result of the conductive adhesive 14 being directly applied to the surface 16 of the substrate 12, the need for a conventional substrate required by conventional PCB's is eliminated. The substrate 12 of FIG. 1 may simply be a portion of the product that has been appropriated for use by the electronic circuit 10. Even so, the substrate 12 still acts and functions much the same as the conventional substrate in many ways. This configuration increases the useable space within, for example, an electronic device. For example, the interior cavity of the electronic device, where electronic components 18 are typically mounted, is more efficiently utilized.

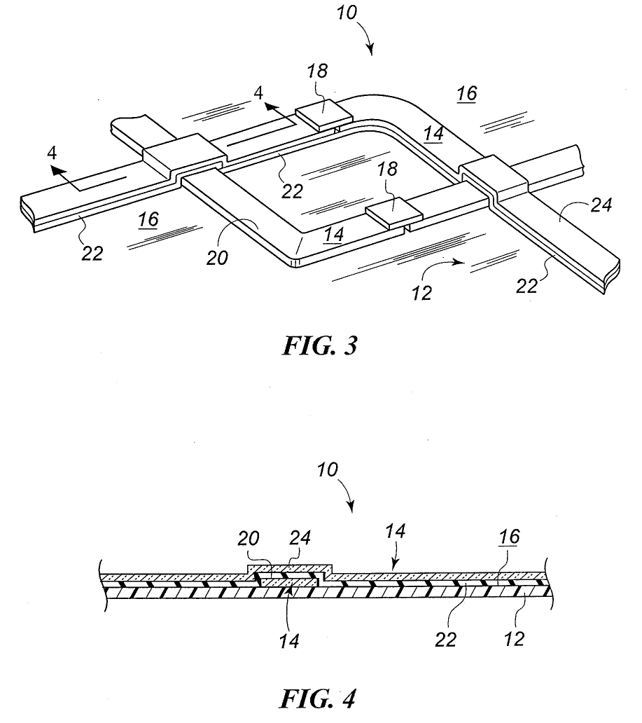

In the embodiment illustrated in FIG. 3, the conductive adhesive 14 is applied to the substrate 12 in the form a first trace 20. After the first trace 20 has been mapped onto the substrate 12, the electrical components 18 are secured to the first trace. The electrical components 18 are situated upon the first trace 20 in predetermined locations or according to a predetermined component layout.

With the first trace 20 secured to the substrate 12 and the electrical components positioned on the first trace, a dielectric material 22 is applied. The dielectric material 22 may be sprayed, printed or otherwise applied to the substrate 12. When applied according to a predetermined path where it encounters the first trace 20, the dielectric material continues over and lays upon the first trace. In one embodiment, the dielectric material 22 is a dielectric spray coating, a strip of dielectric material, a dielectric paste, or another type of dielectric material.

In one embodiment, the dielectric material 22 need not cover a substantial portion of the substrate and may be restricted to areas surrounding or proximate the first trace 20. In other words, the dielectric material may be truncated or otherwise restricted in size and area. For example, in one embodiment the dielectric material 22 may cover only the underlying trace (e.g., the first trace 20) and a portion of the substrate to adjacent to that underlying trace. Also, the dielectric material 22 may have a pattern or path that causes the dielectric material to cover some or all of the electrical components 18 on the first trace 20.

With the dielectric material 22 in place, the conductive adhesive 14 is applied upon the dielectric material 22, the substrate 12, and/or the first trace 20 in the form of a second trace 24. As shown in FIG. 3, where the first and second traces 20, 24 intersect, the second trace is electrically isolated from the first trace by the dielectric material. Like above, after the second trace 24 has been mapped onto the substrate 12, the electrical components 18 are secured to the second trace. The electrical components 18 are situated upon the second trace 24 in predetermined locations or according to a predetermined component layout. This process of stacking traces (e.g., 20, 24) on either side of dielectric material 22 continues until a circuit having a number of traces, a number of electrical components, or satisfies another parameter is completed. This enables multilayer circuit capability far beyond conventional PCB limits. Specifically, unlike conventional multilayer PCB's that require a substrate for every level or layer of electronic circuitry, multilayer electronic circuits 10 constructed with the conductive adhesive 14 need only one initial substrate layer to build upon.

In the illustrated embodiment of FIG. 4, the substrate 12 is depicted as a portion of a plastic housing. As shown, the first trace 20 of conductive adhesive 14 passes underneath the dielectric material 22 and the dielectric material 22 is overlaid with the second trace 24 of conductive adhesive.

In addition to the above, because the electronic components 18 are mechanically coupled to the substrate 12 using the conductive adhesive 14, the electronic circuit 10 of FIG. 1 is substantially or completely free of solder. As a result, the Restriction of the Use of Certain Hazardous Substances (RoHS) regulations mandating environmental responsibility regarding hazardous materials are more easily met.

From the foregoing, those skilled in the art will appreciate that the invention has a myriad of diverse applications. As an example, the electronic circuit 10 is employed in consumer electronics devices where, due to their size, internal space is at a premium. Such devices include, but are not limited to, cell phones, digital cameras, computers, and the like. In such examples, the electronic circuit 10 preferably employs a portion of the device's housing to form the substrate 12. In other applications, the electronic circuit 10 is placed in or on greeting cards, promotional materials, and other paper or non-ridged housing products.

Other advantages of the electronic circuit 10 are readily apparent as well. For example, by eliminating the conventional substrate layer found in PCB's and taking advantage of the existing adjacent housing or product, the electronic circuit 10 has lower production costs. No additional conventional substrate must be purchase or made. The electronic circuit 10 also has a higher level of integration which increases its reliability. In addition, by incorporating existing adjacent structure, the electronic circuit 10 eliminates wasted mechanical space.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. An electronic circuit, comprising:
a non-conductive substrate;
a conductive adhesive adhered to the substrate in a pattern; and
at least one electronic component supported by and electrically connected via the conductive adhesive.

2. The electronic circuit of claim 1, wherein the non-conductive substrate is a housing of an electronic device.

3. The electronic circuit of claim 2, wherein the housing defines an internal surface, the conductive adhesive being adhered to the internal surface.

4. The electronic circuit of claim 1, wherein the non-conductive substrate is flexible, and wherein the conductive adhesive remains flexible after adherence to the non-conductive substrate.

5. The electronic circuit of claim 1, wherein the non-conductive substrate comprises a conductive layer and an insulating layer separating the conductive adhesive from the conductive layer.

6. The electronic circuit board of claim 1, wherein the non-conductive substrate is at least one of paper, plastic, and glass.

7. An apparatus, comprising:
a housing having an internal surface;
a conductive adhesive adhered to the internal surface; and
at least one electronic component mechanically supported by and electrically connected via the conductive adhesive to form a first electronic circuit.

8. The apparatus of claim 7, wherein the internal surface of the housing is contoured.

9. The apparatus of claim 7, wherein the conductive adhesive is formed on the internal surface of the product in a trace pattern.

10. The apparatus of claim 7, further comprising a printed circuit board (PCB) positioned within the housing, the PCB including a second electronic circuit.

11. The apparatus of claim 10, wherein the first electronic circuit formed on the housing and the second electronic circuit formed on the PCB are electrically coupled.

12. A method of increasing useable space within a housing of a device, the method comprising the steps of:
adhering a conductive adhesive to the housing; and
electrically connecting one or more electronic components with the conductive adhesive.

13. The method of claim 12, wherein the method further comprises the step of mechanically supporting the one or more electronic components with the conductive adhesive.

14. The method of claim 12, wherein the method further comprises the step of adhering the conductive adhesive to the housing in at least one of a circuit layout pattern and a trace pattern.

15. The method of claim 12, wherein the method further comprises the step of applying the conductive adhesive to the housing by one of a silk screening, spraying, X-Y plotting, printing, and stenciling process.

16. The method of claim 12, wherein the step of electrically connecting is performed without soldering.

17. The method of claim 12, wherein the step of electrically connecting is performed by pressing the one or more electronic components into the conductive adhesive.

18. The method of claim 12, wherein the method further comprises the step of placing an insulating layer over the conductive adhesive and adhering an additional conductive adhesive layer upon the insulating layer.

17. A method of creating an electronic circuit on a non-conductive product, the method comprising the steps of:
adhering a conductive adhesive to the non-conductive product; and
electrically connecting one or more electronic components using the conductive adhesive.

18. The method of claim 17, wherein the method further comprises the step of structurally supporting the one or more electronic components with the conductive adhesive.

19. The method of claim 17, wherein the method further comprises the step of adhering the conductive adhesive to the non-conductive product in a trace pattern.

20. The method of claim 17, wherein the method further comprises the step of alternating layers of the conductive adhesive and insulating material.
